(19) United States
(12) Patent Application Publication
(10) Pub. No.: US 2002/0066717 A1
(43) Pub. Date: Jun. 6, 2002

(54) Apparatus for providing ozonated process fluid and methods for using same

(76) Inventors: Steven Verhaverbeke, San Francisco, CA (US); Gerald N. DiBello, West Chester, PA (US)

Correspondence Address: Mitchell R. Brustein, WOODCOCK WASHBURN KURTZ, MACKIEWICZ & NORRIS LLP, One Liberty Place - 46th Floor, Philadelphia, PA, 19103, US

(21) Appl. No.: 09/727,661

(22) Filed: Dec. 1, 2000

Related U.S. Application Data
(60) Provisional application No. 60/168,487, filed on Dec. 2, 1999.

(51) Int. Cl. H01B 13/00; C23C 16/00

(52) U.S. Cl. 216/13; 118/722

(57) ABSTRACT

The present invention is directed to apparatus and methods for wet processing electronic components using ozonated process fluids. In the apparatus and methods of the present invention, the ozonated process fluid is provided by an apparatus having a vessel for containing a stock fluid; an ozone source connected to the vessel for supplying ozone to the vessel; a fluid source in fluid communication with the vessel for supplying a fluid to the vessel; and a back-pressure regulator connected with an exhaust for regulating pressure within the vessel.

### FIELD OF THE INVENTION

The present invention is directed to wet processing methods for the manufacture of electronic components including electronic component precursors. More specifically, this invention relates to apparatus for producing ozonated process fluids and methods of using the same to process electronic components.

### BACKGROUND OF THE INVENTION

Wet processing of electronic components, such as semiconductor wafers, flat panels, and other electronic component precursors is used extensively during the manufacture of integrated circuits. Semiconductor fabrication is described generally, for example, in P. Gise et al., Semiconductor and Integrated Circuit Fabrication Techniques (Reston Publishing Co. Reston, Va. 1979), the disclosure of which is herein incorporated by reference in its entirety.

Preferably, wet processing is carried out to prepare the electronic components for processing steps such as diffusion, ion implantation, epitaxial growth, chemical vapor deposition, hemispherical silicon grain growth, or combinations thereof. During wet processing, the electronic components are contacted with a series of processing solutions. The processing solutions may be used, for example, to etch, remove photoresist, clean, grow an oxide layer, or rinse the electronic components. See, e.g., U.S. Pat. Nos. 4,577,650; 4,740,249; 4,738,272; 4,856,544; 4,633,893; 4,778,532; 4,917,123; and EP 0 233 184, assigned to a common assignee, and Burkman et al., Wet Chemical Processes-Aqueous Cleaning Processes, pg 111-151 in Handbook of Semiconductor Wafer Cleaning Technology (edited by Werner Kern, Published by Noyes Publication Parkridge, N.J. 1993), the disclosures of which are herein incorporated by reference in their entirety.

There are various types of systems available for wet processing. For example, the electronic components may be processed in a single vessel system closed to the environment (such as a Full-Flow™ system supplied by CFM Technologies, Inc.), a single vessel system open to the environment, or a multiple open bath system (e.g., wet bench) having a plurality of baths open to the atmosphere.

Following processing, the electronic components are typically dried. Drying of the semiconductor substrates can be done using various methods, with the goal being to ensure that there is no contamination created during the drying process. Methods of drying include evaporation, centrifugal force in a spin-rinser-dryer, steam or chemical drying of wafers, including the methods and apparatus disclosed in, for example, U.S. Pat. Nos. 4,778,532 and 4,911,761.

An important consideration for an effective wet processing method is that the electronic component produced by the process be ultraclean (i.e., with minimum particle contamination and minimum chemical residue). An ultraclean electronic component is preferably free of particles, metallic contaminants, organic contaminants, and native oxides; has a smooth surface; and has a hydrogen-terminated surface. Although wet processing methods have been developed to provide relatively clean electronic components, there is always a need for improvement because of the intricacies associated with technological advances in the semiconductor industry. One of the most challenging problems of attaining ultraclean products is the removal of photoresist.

The use of ozone for removing organic material, such as photoresist, from semiconductor wafers has been investigated. For example, U.S. Pat. No. 5,464,480 issued to Matthews (hereinafter “Matthews”), describes a process in which semiconductor wafers are contacted with a solution of ozone and water at a temperature of about 1° C. to about 15° C. Matthews discloses, for example, placing the semiconductor wafers into a tank containing deionized water, diffusing ozone into the deionized water for a time sufficient to oxidize the organic materials from the wafers, while maintaining the temperature of the water at between about 1° C. to about 15° C., and then rinsing the wafers with deionized (DI) water. Matthews further discloses exposing the wafers to ultraviolet light during the process.

Various other methods have been investigated using ozone in conjunction with water to strip organic materials from the surface of semiconductor wafers or to rinse wafers after chemical processing. For example, in one such method, ozone gas is generated in an ozone generator and fed to an ozonator where the ozone gas is mixed with DI water. The ozone gas is also simultaneously fed to the bottom of the process vessel via a specially designed device that provides a uniform stream of gaseous ozone into the bath. Matthews et al., Mat. Res. Soc. Symp. Proc., 1997, 477, 173-78. See also 1997 Joint Int's Mtg of Electro. Chem. Soc'y and Int'l Soc'y. of Electro., Abstract 1886, p. 2169 submitted by Kenens et al.; Id. at Abstract 1887, p. 2170, submitted by Wolke et al.; Id. at Abstract 1892, p. 2176, submitted by Fukazawa et al.; Id. at Abstract 1934, p. 2236, submitted by Kashkoush et al.; Id. at Abstract 1890, p. 2173, submitted by Li et al.; Id. at Abstract 1891, p. 2174, submitted by Joo et al.; Ultra Clean Processing of Silicon Surfaces UCPSS '96, Kenens et al., Removal of Organic Contamination From Silicon Surfaces, p. 107-110.

In another method, the use of ozone-injected ultrapure water (ozone concentration of about 1-2 ppm) is applied to the RCA or other similar cleaning methods. The ozonated water is used to remove organic impurities. The wafers are then treated with NH₄OH and H₂O₂ to remove metallic ion contaminants, followed by a treatment with HF and H₂O₂ to remove native oxide and metal, and to improve surface smoothness. The wafers are then rinsed with DI water. The ozone gas is generated by electrolyzing ultra pure water. The generated ozone gas is then dissolved in ultrapure water through a membrane. Ohmi et al., J Electrochem. Soc'y, 140, 1993, 804-10.

Another method uses a moist ozone gas phase. In this method, a quartz container is filled with a small amount of liquid, sufficient to immerse an O₃ diffuser. The liquid is DI water spiked with additives such as hydrogen peroxide or acetic acid, if appropriate. A lid is placed on the container and the liquid is heated to 80° C. Wafers are placed directly above the liquid interface (i.e., the wafers are not immersed in the liquid). Heating of the liquid in a sealed container and continuous O₃ bubbling through the liquid exposes the wafers to a moist ambient O₃ environment. De Gendt et al., Symp. VLSI Tech. Dig. Tech. Papers, 1998, 168-69. The De Gendt paper further describes a method whereby a quartz tank is filled with 7 liters of liquid, an ozone diffuser is located at the bottom of the tank, and the liquid is heated. The wafers are positioned directly above the ozone diffuser and immersed in the liquid such that O₂/O₃ bubbles contact the wafer surfaces. The De Gendt paper also reports that OH radical scavengers such as acetic acid can enhance process efficiency.

In another method, photoresist removal is carried out in a gas phase reactor at a temperature of between about 200-300° C. In certain instances, additives such as N₂O gas are mixed with the ozone gas. See Olness et al., Mat. Res. Soc'y. Symp., 135, 1993, 261-66.

Spin cleaning techniques using ozonated water have also been investigated. See, e.g., Cleaning Technology In Semiconductor Device Manufacturing Symposium, Yonekawa et al., Contamination Removal By Wafer Spin Cleaning Process With Advanced Chemical Distribution System, 94-7, 94-101; 1997 Joint Int's Mtg. of Electro. Chem. Soc'y and Int'l Soc'y. of Elctro., Abstract 1888, p. 2171 submitted by Osaka et al.

The use of ozone with cleaning solutions has also been investigated. One such method uses a wafer cleaning sequence with a single-wafer spin using ozonated water and dilute HF to remove contaminants such as particles, metallics, and organics from the wafer surfaces. The method consists of pouring ozonated water on a wafer surface for 10 seconds, followed by pouring dilute HF over the wafers for 15 seconds. This cycle is repeated until the desired results are achieved. 1997 Joint Int's Mtg. of Electro. Chem. Soc'y and Int'l Soc'y. of Elctro., Abstract 1888, p. 2171 submitted by Tsutomu et al; see also Id. at Abstract 1889, p. 2172, submitted by Han et al; Id. at Abstract 1892, p. 2176, submitted by Fukazawa et al; Ultra Clean Processing of Silicon Surfaces UCPSS '96, Kenens et al, Removal of Organic Contamination From Silicon Surfaces, p. 107-10.

Cleaning of semiconductor wafers has also been carried out using gaseous ozone and other chemicals such as hydrofluoric acid and hydrochloric acid to remove residual contaminating particles. For example, U.S. Pat. No. 5,181,985 to Lampert et. al., (hereafter, “Lampert”) discloses a cleaning process where water is sprayed at a temperature of 10° C. to 90° C. onto semiconductor wafers and a chemically active gaseous substance such as ammonia, hydrogen chloride, ozone, ozonized oxygen, chlorine, or bromine is introduced. In Lampert, ozone or ozonized oxygen is used to form a superficial oxide which is then subsequently removed with hydrofluoric acid or hydrochloric acid.

Ozone has also been used in conjunction with sulfuric acid as a means for stripping photoresist from semiconductor wafers. See, e.g., U.S. Pat. Nos. 4,899,767 and 4,917,123 issued to CFM Technologies. The methods described in the CFM patents are carried out in a single vessel system and, generally, a solution of sulfuric acid is spiked with an oxidizing agent such as ozone. Other systems using sulfuric acid in conjunction with ozone may employ a gas distribution system that includes a sparger plate with holes for distributing gas through a bath in the tank. See, e.g., U.S. Pat. No. 5,082,518 assigned to SubMicron. SubMicron's patent describes the use of an apparatus that distributes ozone directly into the treatment tank containing the sulfuric acid.

Ozone ashing has also been investigated as a means for removing photoresist material from wafers. In this method, photoresist is oxidized at higher temperatures (250-350° C.) by two strong oxidizing gases, ozone and atomic oxygen. A small amount of excited nitrous oxide enhances the ashing rate. See Olness et al., Mat. Res. Soc'y. Symp., 135, 1993, 261-66.

U.S. Pat. No. 5,503,708 to Koizumi et al., (“Koizumi”) discloses an alternative apparatus and method using gaseous ozone for removing a photoresist film from a semiconductor wafer. In Koizumi, an apparatus is used that processes a single wafer at a time. The apparatus exposes the wafer to a gas mixture containing ozone and alcohol while the wafer surface is preferably heated to a temperature of 150° C. to 250° C. to effect removal of the photoresist.

The use of ozone in precleaning steps has also been explored. In one such method, as disclosed in U.S. Pat. No. 5,762,755 to McNeilly et al, a wafer contaminated with organics is held in a partial vacuum and heated to at least 200° C. by radiation and then exposed to ozone. The wafer is then cooled to, or below, 80° C. and then exposed to ultraviolet excited chlorine.

Another method for pre-cleaning wafers uses an O₃/IR process as an in situ cleaning step for organic removal before oxide etching to condition the surface and to assure etch repeatability and uniformity. As a post-treatment step, a thin layer of oxide may be grown on the wafer surface. In this process, the ozone is fed into the process chamber while the wafer is being heated by an infrared lamp to a certain temperature, after which the ozone is turned off and the wafer is cooled down by a low temperature inert gas. Cleaning Technology In Semiconductor Device Manufacturing Symposium, Kao et al., Vapor-Phase pre-Cleans for Furnace-Grown and Rapid-Thermal Thin Oxides, 1992, 251-59.

The use of ozone gas in conjunction with ultraviolet light for cleaning and etching wafer surfaces has also been investigated. See Semiconductor Wafer Cleaning and Surface Characterization (proceedings of the 2^{nd} workshop), Moon, Si Wafer Cleaning Study by UV/Ozone ands In Situ Surface Analysis, 68-76; ASM Int'l, Li et al., UV/Ozone Pre-Treatment on Organic Contaminated Wafer for Complete Oxide Removal in HF Vapor Cleaning.

Although the use of ozone has been investigated for use in wet processing techniques, there are still many drawbacks. For example, it is difficult and/or time consuming to obtain significantly high ozone concentrations using the known processes. This shortcoming is exacerbated when ozone is dissolved in water because the ozone decays very quickly. This decay of ozone can be even further accelerated by such factors as increasing the pH of the solution. Thus, there is a need to provide ozone in a form that is readily deliverable to the surfaces of the electronic components at ozone concentrations that are sufficiently high to effectuate the desired processing.

Although gaseous ozone has been used alone and in combination with other gaseous substances to improve the rate of processing of electronic components, the use of gaseous ozone has disadvantages as well. For example, gaseous ozone undesirably leaves oxidized organic byproducts on the electronic components which must subsequently be removed, often requiring additional apparatus. Furthermore, processing, especially when performed to remove photoresist, is typically done at high temperatures (greater than 150° C. and more commonly greater than 250° C.). These high temperatures can lead to malfunctions in the electronic component. Another disadvantage is that many systems currently used for processing electronic components with gaseous ozone process a single wafer at one time and/or are not able to perform several processing steps in one vessel.

Thus, there is the need in the art for a simple and efficient method that permits the safe chemical treatment of electronic components with ozone, while at the same time providing an environmentally safe and economical method.

The present invention meets these as well as other needs. For example, the present invention provides apparatus and methods for readily delivering ozone in a stable form to electronic components during wet processing. The ozone is delivered to the electronic components to effectuate any of a variety of processes including, but not limited to, oxide growth, removal of organic contaminants (e.g., removal of photoresist), pre-cleaning, etching, and cleaning. Also, the present invention provides apparatus and methods for exposing the electronic components to substantially bubble-free ozonated process fluids, having high concentrations of ozone, at various temperatures.

### SUMMARY OF THE INVENTION

The present invention provides, inter alia, wet processing apparatus and methods for the manufacture of electronic components, including electronic component precursors such as semiconductor wafers used in integrated circuits. More specifically, this invention relates to apparatus and methods for processing electronic components using wet processing techniques with ozonated process fluids. In particular, the apparatus and methods of the invention may be used, inter alia, to remove organic materials (e.g., photoresists) from electronic components and to oxidize the surfaces of the electronic components (i.e., growth of an oxide layer). The apparatus and methods of the present invention may also be used in pretreatment steps such as cleaning or etching.

In one of its aspects, the present invention relates to apparatus for providing an ozonated process fluid. The apparatus comprise a vessel for containing a stock fluid and an ozone source operatively connected with the vessel for supplying ozone to the vessel. A packing material is optionally contained within the vessel. In one particular embodiment, the ozone source comprises an ozone generator operatively connected and in fluid communication with an inlet of the vessel. Further, the ozone source optionally comprises a sparger to facilitate the dissolution of ozone in the fluid contained in the vessel. A fluid source is operatively connected and in fluid communication with the vessel for supplying a fluid to the vessel. In one embodiment, the fluid source comprises an inert gas source for supplying an inert gas to the vessel. The fluid source optionally comprises a pressure regulator for regulating the pressure of the inert gas. In addition, an exhaust is operatively connected and in fluid communication with the vessel for venting fluid from the vessel. Pressure within the vessel is regulated using a back-pressure regulator operatively connected with the exhaust. A screen is optionally positioned within the vessel to substantially span the open end of the vessel. An outlet is positioned about an open end of the vessel for connecting the vessel to an injection manifold. The injection manifold is provided for receiving an ozonated fluid from the vessel. In addition, a water source can be operatively connected and in fluid communication with the injection manifold for supplying water to the injection manifold. An injection controller is optionally operatively connected with the injection manifold, the vessel, and the water source for controlling the flow of water and ozonated fluid through the injection manifold. A temperature controller is optionally operatively associated with the injection manifold for adjusting the temperature of the water from the water source.

In another of its aspects, the present invention relates to methods for producing an ozonated process fluid. The methods comprise bubbling ozone through a stock fluid contained in a pressurizable vessel. A partial pressure of the ozone within the pressurizable vessel is regulated to facilitate dissolution of ozone within the stock fluid and to provide an ozonated fluid. The ozonated fluid is mixed with water to form the ozonated process fluid.

In yet another of its aspects, the present invention relates to methods for processing an electronic component with an ozonated process fluid. The methods comprise bubbling ozone through a stock fluid contained in a pressurizable vessel. A partial pressure of the ozone within the pressurizable vessel is regulated to dissolve ozone within the stock fluid and to provide an ozonated fluid. A fluid is introduced into the vessel to expel the ozonated fluid from the vessel and into an injection manifold. A flow of water is optionally supplied to the injection manifold such that the water mixes with the ozonated fluid to form the ozonated process fluid. The electronic component is then contacted with the ozonated process fluid.

### BRIEF DESCRIPTION OF THE DRAWING

The numerous objects and advantages of the present invention may be better understood by those skilled in the art by reference to the accompanying detailed description and the following drawing, in which:

FIG. 1 is a schematic, perspective view of an apparatus for providing an ozonated process fluid in accordance with the present invention.

### DETAILED DESCRIPTION OF THE INVENTION

The present invention provides apparatus and methods for wet processing electronic components using an ozonated process fluid. The apparatus and methods of the present invention are particularly useful for removing organic materials from the surfaces of electronic components using the ozonated process fluid. For example, during wet processing, the apparatus and methods of the present invention can be used to remove organic materials such as photoresists (ashed or unashed), plasticizers, surfactants, fluorocarbon polymers, organics from human contact, or combinations thereof. The apparatus and methods of the invention may also be used to grow an oxide layer on the electronic component surface. The apparatus and methods of the invention are also contemplated to be used for pretreatment cleaning, etching, cleaning between processing steps, as well as post-treatment cleaning and processing (e.g., oxide growth).

The present invention also provides apparatus and methods for using an ozonated process fluid where a plurality of electronic components can be treated with the ozonated process fluid simultaneously and/or where the electronic components can be subsequently contacted with other process fluids in the same processing chamber. Without intending to be bound by any particular theory, the present invention is believed to function by increasing the ozone diffusion gradient within the ozonated process fluid. The increased ozone diffusion gradient enables higher concentrations of ozone to be achieved and/or decreases the time required to reach a given ozone concentration.

The terminology “wet processing” or “wet process” as used herein means the electronic components are contacted with one or more liquids (hereinafter referred to as “process liquids” or “process solutions”) to process the electronic components in a desired manner. For example, it may be desired to treat the electronic components to clean, etch, or remove photoresist from the surfaces of the electronic components. It may also be desired to rinse the electronic components between such treatment steps.

Wet processing may also include steps where the electronic components are contacted with other fluids, such as a gas, a vapor, a liquid mixed with a vapor or gas, or combinations thereof. As used herein, the term “process fluid” includes liquids, gases, liquids in their vapor phases, or combinations thereof. The terminology “vapor” as used herein is meant to include partially vaporized liquid, saturated vapor, unsaturated vapor, supersaturated vapor or combinations thereof.

There are various types of process fluids used during wet processing. Generally, the most common types of process fluids used during wet processing are reactive chemical process fluids or liquids, and rinsing fluids or liquids. The terminology “reactive chemical process fluid” or “reactive chemical process liquid” as used herein, is any liquid or fluid that reacts in some desired manner with the surfaces of the electronic components to alter the surface composition of the electronic component. For example, the reactive chemical process liquid or fluid may have activity in removing contamination adhered or chemically bound to the surfaces of the electronic components, such as particulate, metallic, photoresist, or organic materials; activity in etching the surfaces of the electronic component; or activity in growing an oxide layer on the surface of the electronic component. As used herein, “rinsing liquid” or “rinsing fluid” refers to DI water or some other liquid or fluid that removes from the electronic components and/or processing chamber residual reactive chemical process fluids, reaction by-products, and/or particles or other contaminants freed or loosened by the chemical treatment step. The rinsing liquids or fluids may also be used to prevent redeposition of loosened particles or contaminants onto the electronic components or processing chamber. Examples of reactive chemical process fluids and rinsing fluids useful in the methods of the present invention are described in more detail hereinafter.

As used herein, “chemical treatment step” or “wet processing step” refers to contacting the electronic components with a reactive chemical process fluid or rinsing fluid, respectively.

The terminology “process chamber” and “reaction chamber,” as used herein, refer to vessels (enclosed or open to the atmosphere), baths, wet benches and other reservoirs suitable for wet processing electronic components. The terminology “single vessel,” refers to any wet processing system in which the electronic components are maintained in one processing chamber during the entire wet processing sequence.

The terminology “electronic components,” as used herein, includes for example electronic component precursors such as semiconductor wafers, flat panels, and other components used in the manufacture of electronic components (i.e., integrated circuits); CD ROM disks; hard drive memory disks; or multichip modules.

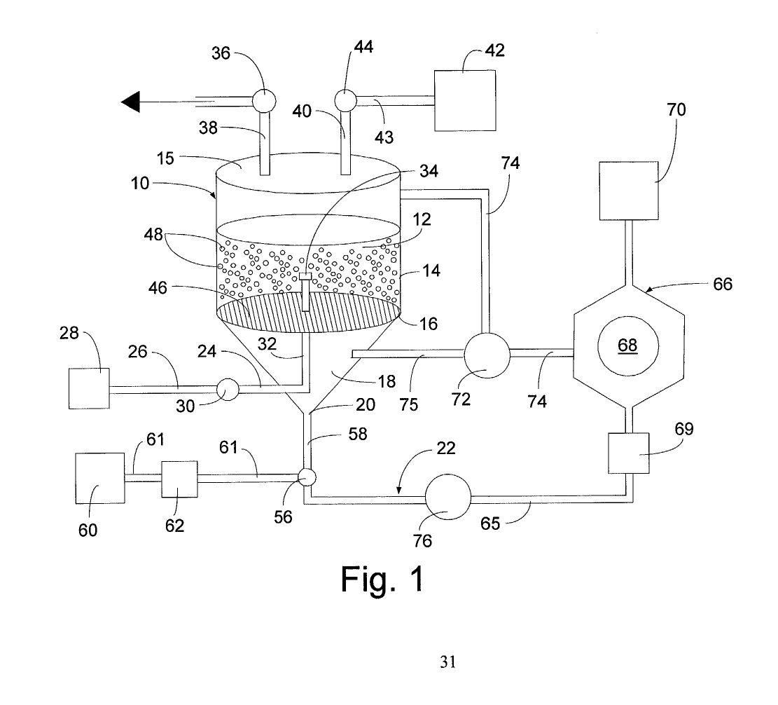

In particular, the present invention relates to an apparatus for providing an ozonated process fluid, as shown in FIG. 1. The apparatus comprises a pressurizable injection tube 10 for containing a stock fluid 12 (e.g., water). It would be appreciated by those skilled in the art that the injection tube 10 can be formed as any pressurizable chamber or vessel capable of containing the stock fluid at the pressures described in detail below. The injection tube 10 comprises a portion 14 having a sealed upper end 15 and an opened lower end 16. As shown, a frustoconical section 18 extends from the opened lower end 16 of the portion 14. However, it will be appreciated that the opened lower end 16 of the portion 14 can have a shape which is not frustoconical. In one embodiment, the frustoconical section 18 is integrally formed with the portion 14. The frustoconical section 18 provides the injection tube 10 with a slanted bottom to facilitate removal of fluid from the injection tube 10 through an opening 20 in the frustoconical section 18. It will be appreciated that the portion 14 and frustoconical section 18 of the injection tube 10 define an interior volume for holding the stock fluid. Accordingly, the opening 20 in the frustoconical section 18 serves as an outlet for discharging fluid from the interior of the injection tube 10. The outlet provides a conduit which can be connected to an injection manifold 22 to provide fluid communication between the injection tube 10 and the injection manifold 22. In one particular embodiment, the injection tube 10 is formed from a pressurized injection tube.

The injection tube 10 can be constructed of any material which is substantially inert to ozone and which can be made to withstand the internal pressures achieved during use of the apparatus (e.g., about 3 atmospheres). However, preferred materials include glass, quartz, Pyrex®, aluminum, stainless steel, Halar® (available from Ausimont), polyfluoroalkoxy resin (PFA), and polytetrafluoroethylene (PTFE). The size of the injection tube 10 can vary and should be selected according to the particular application for which it is to be used. However, the volume of the injection tube 10 is preferably between about 2 and about 4 times the volume of the processing chamber 66, which is described below. For example, the injection tube 10 can provide an interior volume of about 76 liters (20 gallons).

An inlet 24 extends through the frustoconical section 18 of the injection tube 10 to provide fluid communication with the interior of the injection tube 10. An external end of the inlet 24 is operatively connected by tubing 26 to an ozone source. The ozone source comprises an ozone generator 28 and an optional valve 30. In one embodiment, the ozone generator 28 is a high capacity ozone generator capable of providing ozone at pressures in excess of about 2.4 atmospheres (20 psig), and preferably in excess of about 3.4 atmospheres (35 psig). For example, the ozone generator 28 can be a high capacity ozone generator such as that made by Astex under the model number AX8400 series. When provided, the valve 30 is operatively connected between the ozone generator 28 and the inlet 24 for reversibly allowing the flow of ozone to the injection tube 10 to be started and halted.

An internal end of the inlet 24 is in fluid contact with the interior volume of the injection tube 10. For example, the internal end of the inlet 24 can be operatively connected to tubing 32. Accordingly, ozone generated by the ozone generator 28 can be delivered to the internal volume of the injection tube 10 by opening valve 30 and passing the ozone through tubing 26, inlet 24, and tubing 32. A sparger 34 is optionally attached near an open end of the tubing 32 to better dissolve the ozone in the stock fluid contained within the injection tube 10. In one embodiment, the sparger 34 is formed from a sintered polytetrafluororethylene (PTFE) material.

A back-pressure regulator 36 is operatively connected with an exhaust 38 of the injection tube 10. The exhaust 38 is positioned near the upper end 15 of the portion 14 of the injection tube 10 and is in fluid communication with the interior of the injection tube 10. The back-pressure regulator 36 is provided for regulating the pressure within the injection tube 10. The back-pressure regulator 36 functions by venting fluid, especially in the form of moist ozone, when the pressure in the injection tube 10 exceeds a predetermined limit. The moist ozone vented from the regulator 36 can be discarded as waste or utilized for further processing of electronic components. Since the concentration of dissolved ozone in the ozonated fluid is proportional to the partial pressure of ozone in the injection tube 10 above the stock fluid in accordance with Henry's Law (C₀₃∝KP₀₃), the predetermined limit can be adjusted to vary the concentration of dissolved ozone in the fluid. In one embodiment, the pressure within the injection tube 10 is set between about 20 and about 40 psig (between about 2.4 and about 3.8 atmospheres).

An inlet 40 is provided, in or near the top of the injection tube 10, for introducing a working (e.g., pneumatic) fluid, preferably in the form of an inert gas such as nitrogen, into the interior of the injection tube 10. Accordingly, a working fluid source 42 is connected to the inlet 40 via tubing 43. When the fluid source 42 is a source of nitrogen, the fluid source 42 can be in the form of a gas tank or cylinder. A regulator 44 is optionally operatively connected between the fluid source 42 and the inlet 40 for regulating the flow of the working fluid to the injection tube 10.

The apparatus optionally comprises a screen 46 for reducing the size of bubbles present within the ozonated fluid as the ozonated fluid is discharged from the injection tube 10. Accordingly, the use of a screen is particularly preferred when large bubbles in the ozonated fluid would detrimentally affect the processing of the electronic components. For example, bubbles are an issue almost anytime wafers are processed, and especially when the wafers are hydrophobic or contain hydrophobic regions. The screen 46 is optionally positioned within the injection tube 10 substantially spanning the opened lower end 16 of the portion 14 of the injection tube 10 such that all, or substantially all, of any fluid being discharged through the outlet 20 of the injection tube 10 passes through the screen 46. In the embodiment of FIG. 1, the screen 46 is positioned at or near the junction between portion 14 and the frustoconical section 18. Alternatively, the screen 46 can be positioned either above or below the junction between portion 14 and frustoconcial section 18. In one embodiment, the screen 46 is formed from a section of Teflon® mesh having a pore size on the order of 50 μm.

The screen 46 can also function as a support for maintaining a packing material 48 within the interior of the injection tube 10. The packing material 48 can be used to further facilitate dissolution of the ozone in the stock fluid contained within the injection tube 10. In one embodiment, the packing material 48 comprises polytetraalkoxy resin (PTA) chips or cubes.

The injection manifold 22 comprises an injection controller 56 having a first inlet operatively connected with the outlet 20 of the injection tube 10 via tubing 58. A second inlet is preferably provided on the injection controller 56 for operatively connecting the injection controller 56 to an optional carrier fluid source 60 via tubing 61. In one embodiment, the carrier fluid source 60 is a source of deionized water and, preferably, a source of degassified deionized water. The injection controller 56 controls mixing of the ozonated fluid from the injection tube 10 with the carrier fluid from the carrier fluid source 60 to form the ozonated process fluid. Mixing the ozonated process fluid with a carrier fluid may be desired, for example, when the presence of bubbles in the ozonated process fluid is to be avoided. The injection controller 56 preferably comprises a rotometer for measuring and controlling the flow of the carrier fluid. Adjusting the flow rate through the injection controller 56 enables the concentration of ozone in the ozonated process fluid to be adjusted.

A temperature controller 62 is optionally operatively connected between the carrier fluid source 60 and the injection controller 56. It will be appreciated by those skilled in the art that the temperature controller 62 can be integrally formed with the carrier fluid source 60. The temperature controller 62 is used to adjust the temperature of the carrier fluid prior to mixing the carrier fluid with the ozonated fluid. In one embodiment, the temperature of the carrier fluid is adjusted to be between about 20° C. and about 80° C. Adjusting the temperature of the carrier fluid, in turn, alters the temperature of the ozonated processing fluid. The temperature of the ozonated processing fluid is inversely proportional to the concentration of dissolved ozone in the ozonated processing fluid (i.e., the higher the temperature of the ozonated processing fluid, the lower the concentration of dissolved ozone). By altering the flow (as discussed above) and the temperature of the carrier fluid, the final concentration of ozone in the ozonated processing fluid can be varied throughout a range of about 0 ppm and about 60 ppm.

The injection manifold 22 further comprises tubing 65 for conducting or transferring the ozonated process fluid to a processing chamber 66 for wet processing of the electronic components 68. A pump 76 is optionally operatively connected to tubing 65 to facilitate flowing the process fluid to the chamber 66. It will be appreciated, however, that alternate means for transferring the ozonated process fluid to the processing chamber 66 can be utilized. A temperature and flow controller 69 is optionally operatively connected between the injection manifold 22 and the processing chamber 66 for measuring the temperature and flow rate of the ozonated process fluid as it enters the processing chamber 66. Adjusting the temperature and flow rate of the ozonated process fluid enables the concentration of ozone reaching the processing chamber 66 to be controlled to suit the particular application for which the apparatus is being used.

There are various types of ways in which the electronic components can be wet processed in accordance with the present invention. For example, wet processing can be carried out using sonic energy (such as in the megasonic energy range) during the contacting of the electronic components with the ozonated process fluid to enhance cleaning. Such methods may also include wet processing techniques disclosed in for example U.S. Pat. No. 5,383,484; U.S. patent application Ser. No. 08/684,543, filed Jul. 19, 1996; Ser. No. 09/209,101, filed Dec. 10, 1998; and Ser. No. 09/253,157, filed Feb. 19, 1999; and U.S. Provisional Patent Application Ser. No. 60/087,758 filed Jun. 2, 1998;and No. 60/111,350 filed Dec. 8, 1998, the disclosures of which are all hereby incorporated by reference in their entireties.

The present invention may be carried out using a process chamber 66 comprising generally any of the known wet processing systems including, for example, multiple bath systems (e.g., wet bench) and single processing chamber systems (open or closable to the environment). See, e.g., Chapter 1: Overview and Evolution of Semiconductor Wafer Contamination and Cleaning Technology by Werner Kern and Chapter 3: Aqueous Cleaning Processes by Don C. Burkman, Donald Deal, Donald C. Grant, and Charlie A. Peterson in Handbook of Semiconductor Wafer Cleaning Technology (edited by Werner Kern, Published by Noyes Publication Parkridge, New Jersey 1993), and Wet Etch Cleaning by Hiroyuki Horiki and Takao Nakazawa in Ultraclean Technology Handbook, Volume 1, (edited by Tadahiro Ohmi published by Marcel Dekker), the disclosures of which are herein incorporated by reference in their entirety. However, the use of a closable bath is preferred, especially for applications where bubbles in the ozonated process fluid are to be avoided (i.e, for the processing of hydrophobic wafers or wafers containing hydrophobic regions). In addition, the wet processing system optionally comprises a recirculator for circulating the ozonated process fluid within the injection tube 10 and/or for returning used ozonated process fluid from processing chamber 66 to injection tube 10. As shown in FIG. 1, the recirculator comprises a pump 72 connected between the processing chamber 66 and the injection tube 10 by tubing 74. The pump 72 removes used ozone processing fluid from the processing vessel 66 and returns it to the injection tube 10, where the ozone concentration of the processing fluid can be regenerated. Alternatively, the pump can be used to provide the used ozonated processing fluid to another processing vessel. The pump 72 is also optionally connected between the bottom and the top of injection tube 10 by tubing 75. Accordingly, the pump 72 can be used to circulate the process fluid within the injection tube 10 to facilitate mixing of the process fluid with gaseous ozone.

Preferably the wet processing system will include storage tanks for chemical reagents, such as ammonium hydroxide (NH₄OH) or hydrofluoric acid (HF); and a system for delivering deionized water used for rinsing the electronic components and diluting the chemical reagents. The chemical reagents are preferably stored in their concentrated form, which is: hydrogen peroxide (H₂O₂) (31%), NH₄OH (28%), hydrochloric acid (HCI) (37%), HF (49%), and sulfuric acid (H₂SO₄) (98%) (percentages represent weight percentages in aqueous solutions). The storage tanks are preferably set-up so that they are in fluid communication with the reaction chamber where the electronic components are treated.

In one embodiment of the invention, the electronic components are housed in a single processing chamber system. Preferably, single processing chamber systems such as those disclosed in U.S. Pat. Nos. 4,778,532, 4,917,123, 4,911,761, 4,795,497, 4,899,767, 4,984,597, 4,633,893, 4,917,123, 4,738,272, 4,577,650, 5,571,337 and 5,569,330, the disclosures of which are herein incorporated by reference in their entirety, are used. Preferred commercially available single processing chamber systems are Full-Flow™ vessels such as those manufactured by CFM Technologies, Poseidon manufactured by Steag, and FL820L manufactured by Dainippon Screen. Such systems are preferred because foreign gas and contamination levels can be more readily controlled.

The single vessel wet processing system also preferably includes metering devices such as a control valve and/or pump for transporting chemical reagents from the storage tank area to the reaction chamber. A processing control system, such as a personal computer, is also typically used as a means to monitor processing conditions (e.g., flow rates, mix rates, exposure times, and temperature). For example, the processing control system can be used to program the flow rates of chemical reagents and deionized water so that the appropriate concentration of chemical reagent(s) will be present in the reactive chemical process fluid.

In a most preferred embodiment of the present invention, the electronic components are wet processed in an enclosable single wet processing chamber system. The processing chamber is preferably presurrizable so that the ozonated process fluid can be maintained at pressure above about atmospheric pressure (for example, about 2 psig) to about the same pressure as the ozone produced by the ozone generator 28. Maintaining the ozonated process fluid under pressure within the processing chamber may be desired to prevent ozone bubbles from forming within the ozonated process fluid. Bubbles should especially be avoided when the electronic components being processed are hydrophobic or contain hydrophobic regions. Additionally, an elevated pressure within the processing chamber of the wet processing system may be useful for maintaining a high ozone diffusion rate within the processing chamber, thereby improving processing efficiency.

The enclosable single wet processing chamber system is also preferably capable of receiving different process fluids in various sequences. A preferred method of delivering process fluids to the processing chamber is by direct displacement of one fluid with another. The Full Flow™ wet processing system manufactured by CFM Technologies, Inc. is an example of a system capable of delivering fluids by direct displacement. Such systems are preferred because they result in a more uniform treatment of the electronic components. Additionally, often the chemicals utilized in the chemical treatment of electronic components are quite dangerous in that they may be strong acids, alkalis, or volatile solvents. Enclosable single processing chambers minimize the hazards associated with such process fluids by avoiding atmospheric contamination and personnel exposure to the chemicals, and by making handling of the chemicals safer.

In a preferred embodiment of the present invention using a single, enclosable processing chamber, one or more electronic components are placed in a single processing chamber and closed to the environment. The electronic components may optionally be contacted with one or more process fluids for pretreatment. Following any desired pretreatment step, the electronic components are contacted with the ozonated process fluid. Such contacting can be accomplished through directing the ozonated process fluid into the processing chamber to fill the processing chamber full with the ozonated process fluid so that gases from the atmosphere or residual fluid from a previous step are not significantly trapped within the processing chamber. The ozonated process fluid can be continuously directed through the processing chamber once the processing chamber is full of the ozonated process fluid, or the flow of ozonated process fluid can be stopped to soak the electronic components for a desired time. The ozonated process fluid may then be removed from the processing chamber. Following contact with the ozonated process fluid, the electronic components may be optionally rinsed with a rinsing fluid and/or contacted with another process fluid such as one or more reactive chemical process fluids.

The removal of one process fluid with another process fluid in the enclosable single processing chamber can be accomplished in several ways. For example, the process fluid in the process processing chamber can be substantially completely removed (i.e., drained), and then the next process fluid can be directed into the processing chamber during or after draining. In another embodiment, the process fluid present in the processing chamber can be directly displaced by the next desired process fluid as described for example in U.S. Pat. No. 4,778,532.

In operation, the apparatus is used to process electronic components 68 which are placed within the processing chamber 66 by exposing the electronic components 68 to the ozonated processing fluid. Toward that end, the injection controller 56 is set to seal the outlet 20 of the injection tube 10. The injection tube 10 is then filled with a stock fluid (e.g., water) and the ozone generator 28 is operated to produce ozone. The ozone is bubbled through the stock fluid contained in the injection tube 10 by passing the ozone from the ozone generator 28 through tubing 26, valve 30, inlet 24, and sparger 34. The ozone is allowed to bubble through the stock fluid for a time sufficient to raise the concentration of dissolved ozone within the stock fluid to a desired level. The time will vary according to the particular operating conditions used (e.g., the temperature of the stock fluid, the capacity of the ozone generator 56, the use of optional packing material 48, the use of an optional sparger 34, and the specific setting on the back-pressure regulator 36). However, the ozone is preferably bubbled through the stock fluid for at least about 1-30 minutes, and more preferably for at least about 3 minutes. Alternatively, the concentration of ozone within the stock fluid can be monitored using an ozone detector. After the concentration of dissolved ozone within the stock fluid has reached the desired level, the ozone generator 28 and valve 30 can be adjusted to stop the flow of ozone to the injection tube 10.

When the concentration of dissolved ozone in the stock fluid has reached the desired level (e.g., the ozone has been bubbled through the stock fluid for a sufficient length of time), the pressure regulator 44 is adjusted to allow the working fluid from the fluid source 42 to enter the injection tube 10. As the working fluid fills the interior of the injection tube 10, the ozonated fluid within the injection tube 10 is forced through the outlet 20 of the injection tube 10 and into the injection manifold 22.

The injection controller 56 is then operated to mix the carrier fluid from the carrier fluid source 60 with the ozonated fluid to form the ozonated process fluid. The carrier fluid is optionally spiked with additives which are desired to enhance certain properties of the process fluid. If desired, the temperature controller 62 is operated to adjust the temperature of the carrier fluid, and thereby the temperature of the ozonated process fluid, to the desired level. The ozonated process fluid is then introduced into the processing chamber 66 through tubing 65. Accordingly, the ozonated process fluid is brought into contact with electronic components 68 contained within the processing chamber 66. After the electronic components 68 have been contacted with the ozonated process fluid for a sufficient period of time to effectuate the desired processing of the electronic components 68, the ozonated process fluid is expelled from the processing chamber 66 into a drain 70.

The electronic components may be contacted with the wetting solution in any manner that wets the surfaces of the electronic components with the wetting solution. For example, the electronic components may be immersed and withdrawn from a wetting solution. The electronic components may also be placed in a processing chamber, where the processing chamber is filled and then drained of the wetting solution. The wetting solution may also be applied to the electronic components as a mist. Thus, there are various ways to contact the wetting solution with the electronic components to wet the electronic components. One skilled in the art will recognize that these methods of wetting the electronic components can be varied to adjust the thickness of the layer of wetting solution on the electronic components.

Preferably, the concentration of ozone in the ozonated process fluid expressed as weight of ozone per volume of ozonated process fluid is from about 10 g/m³ to about 300 g/m³, more preferably from about 50 g/m³ to about 250 g/m³, and most preferably from about 100 g/m³ to about 200 g/m³ at standard temperature and pressure (25° C., 1 atm). Although the temperature of the ozonated process fluid that is contacted with the electronic components will depend upon the ozonated process fluid chosen, in general, the temperature of the ozonated process fluid preferably ranges from about 20° C. to about 145° C. and more preferably from about 40° C. to about 120° C. The pressure of the ozonated process fluid during contact with the electronic components is preferably from about 0 psig to about 20 psig, more preferably from about 1 psig to about 10 psig, and most preferably from about 1 psig to about 5 psig. To prevent or reduce the production of ozone bubbles, the ozonated process fluid is maintained at about the same pressure as the ozone generator.

Other process fluids may be present in the ozonated process fluid. Examples of other process fluids include for example water, sulfuric acid, hydrochloric acid, hydrogen peroxide, ammonia hydroxide, hydrofluoric acid (buffered or unbuffered), ammonia fluoride, phosphoric acid, nitric acid, aqua regia, or combinations thereof. As acetic acid is a hydroxyl radical scavenger, preferably, the reaction chamber is substantially free of acetic acid when gaseous ozone is present in the reaction chamber to prevent the scavenging of hydroxyl radicals. The other process fluids may be present in the ozonated process fluid to preferably provide a molar ratio of ozone to the other process fluids in the ozonated process fluid in an amount of from about 1:90 to about 40:1.

The preferred temperatures of the process fluids prior to formation of the ozonated process fluid (e.g., hydroxide fluid or other process fluids) will depend on the form of the process fluid.

The ozonated process fluid once formed, is preferably, immediately contacted with the electronic components in the process chamber for a time to accomplish the desired result. The temperature of the electronic components during contacting is preferably at the temperature of the ozonated process fluid. By “contact time,” as used herein, it is meant the time an electronic component is exposed to a process fluid. For example, the contact time will include the time an electronic component is exposed to the process fluid during filling a processing chamber with the process fluid or immersing the electronic component in the process fluid; the time the electronic component is soaked in the process fluid; and the time the electronic component is exposed to the process fluid while the process fluid or electronic component is being removed from the processing chamber. The actual contact time chosen will also depend on such variables as the temperature, pressure, and composition of the ozonated process fluid, and the composition of the surfaces of the electronic components. Preferably, the contact time with the ozonated process fluid will be for at least 30 seconds.

There various ways in which the electronic components can be contacted with the ozonated process fluid. Some specific embodiments of contacting the ozonated process fluid with the electronic components will now be described. These embodiments are being provided as examples only and are in no way intended to limit the scope of the present invention.

In one embodiment of the present invention, the electronic components are contacted with a wetting solution of water and then contacted with the ozonated process fluid. In addition to the ozonated process fluid, the electronic components may be contacted with any number of other reactive chemical process fluids (e.g., gas, liquid, vapor or any combination thereof) to achieve the desired result. For example, the electronic components may be contacted with reactive chemical process fluids used to etch (hereinafter referred to as etching fluids), grow an oxide layer (hereinafter referred to as oxide growing fluids), to remove photoresist (hereinafter referred to as photoresist removal fluids), to enhance cleaning (hereinafter referred to as cleaning fluids), or combinations thereof. The electronic components may also be rinsed with a rinsing fluid at any time during the wet processing method. Preferably, the reactive chemical process fluids and rinsing fluids are liquids.

The reactive chemical process fluids useful in the present invention contain one or more chemically reactive agents to achieve the desired surface treatment. Preferably, the concentration of such chemically reactive agents will be greater than 1000 ppm and more preferably greater than 10,000 ppm, based on the weight of the reactive chemical process fluid. However, in the case of ozone, generally the concentration is equal to or greater than about 10 ppm and more preferably from about 10 ppm to about 50 ppm. Examples of chemically reactive agents include for example hydrochloric acid or buffers containing the same, ammonium hydroxide or buffers containing the same, hydrogen peroxide, sulfuric acid or buffers containing the same, mixtures of sulfuric acid and ozone, hydrofluoric acid or buffers containing the same, chromic acid or buffers containing the same, phosphoric acid or buffers containing the same, acetic acid or buffers containing the same, nitric acid or buffers containing the same, ammonium fluoride buffered hydrofluoric acid, deionized water and ozone, or combinations thereof.

It is also possible for the reactive chemical process fluid to contain 100% of one or more chemically reactive agents. For example, it may be desired to contact the electronic components with solvents such as acetone, N-methyl pyrrolidone, or combinations thereof. Such solvents are chemically reactive agents used, for example, to remove organics or to provide other cleaning benefits.

Examples of preferred reactive chemical process fluids useful in the present invention include cleaning fluids, etching fluids, and photoresist removal fluids. Cleaning fluids typically contain one or more corrosive agent such as an acid or base. Suitable acids for cleaning include for example sulfuric acid, hydrochloric acid, nitric acid, or aqua regia. Suitable bases include for example, ammonium hydroxide. The desired concentration of the corrosive agent in the cleaning fluid will depend upon the particular corrosive agent chosen and the desired amount of cleaning. These corrosive agents may also be used with oxidizing agents such as ozone or hydrogen peroxide. Preferred cleaning solutions are “SC1” solutions containing water, ammonia, and hydrogen peroxide, and “SC2” solutions containing water, hydrogen peroxide, and hydrochloric acid. Typical concentrations for SC1 solutions range from about 5:1:1 to about 200:1:1 parts by volume H₂O:H₂O₂:NH₄OH. Typical concentrations for SC2 solutions range from about 5:1:1 to about 1000:0:1 parts by volume H₂O:H₂O₂:HCl. Suitable etching solutions contain agents that are capable of removing oxides. A common etching agent used is for example hydrofluoric acid, buffered hydrofluoric acid, ammonium fluoride, or other substances which generate hydrofluoric acid in solution. A hydrofluoric acid containing etching solution may contain for example from about 4:1 to about 1000:1 parts by weight H₂O:HF.

One skilled in the art will recognize that there are various process fluids that can be used during wet processing. Other examples of process fluids that can be used during wet processing are disclosed in “Chemical Etching” by Werner Kern et al., in Thin Film Processes, edited by John L. Vosser et al., published by Academic Press, NY 1978, pages 401-496, which is incorporated by reference in its entirety.

The electronic components may also be contacted with rinsing fluids during the methods of the present invention. As previously described, rinsing fluids are used to remove from the electronic components and/or processing chamber residual reactive chemical process fluids, reaction by-products, and/or particles or other contaminants freed or loosened by a chemical treatment step. The rinsing fluids may also be used to prevent redeposition of loosened particles or contaminants onto the electronic components or processing chamber.

Any rinsing fluid may be chosen that is capable of achieving the effects described above. In selecting a rinsing fluid, such factors as the nature of the surfaces of the electronic components to be rinsed, the nature of contaminants dissolved in the reactive chemical process fluid, and the nature of the reactive chemical process fluid to be rinsed should be considered. Also, the proposed rinsing fluid should be compatible (i.e., relatively non-reactive) with the materials of construction in contact with the fluid. Rinsing fluids which may be used include for example water, organic solvents, mixtures of organic solvents, ozonated water, or combinations thereof. Preferred organic solvents include those organic compounds useful as drying solutions disclosed hereinafter such as C₁ to C₁₀ alcohols, and preferably C₁ to C₆ alcohols. Preferably the rinsing fluid is a liquid and more preferably is deionized water.

Rinsing fluids may also optionally contain low levels of chemically reactive agents to enhance rinsing. For example, the rinsing fluid may be a dilute aqueous solution of hydrochloric acid or acetic acid to prevent, for example, metallic deposition on the surface of the electronic component. Surfactants, anti-corrosion agents, and/or ozone are other additives used in rinsing fluids. The concentration of such additives in the rinsing fluid is minute. For example, the concentration is preferably not greater than about 1000 ppm by weight and more preferably not greater than 100 ppm by weight based on the total weight of the rinsing fluid. In the case of ozone, preferably the concentration of ozone in the rinsing fluid is 5 ppm or less.

One skilled in the art will recognize that the selection of reactive chemical process fluids, the sequence of reactive chemical process fluids and rinsing fluids, and the processing conditions (e.g., temperature, concentration, contact time and flow of the process fluid) will depend upon the desired wet processing results. For example, the electronic components could be contacted with a rinsing fluid before or after one or more chemical treatment steps. Alternatively, it may be desired in some wet processing methods to have one chemical treatment step directly follow another chemical treatment step, without contacting the electronic components with a rinsing fluid between two chemical treatment steps (i.e., no intervening rinse). Such sequential wet processing, with no intervening rinse, is described in for example U.S. application Ser. No. 08/684,543 filed Jul. 19, 1996, which is hereby incorporated by reference in its entirety.

In a preferred embodiment of the present invention, the electronic components are contacted with at least one processing fluid that is a liquid (i.e., processing solution) subsequent to contact with the ozonated process fluid to aid in removal of reaction by products or residual chemicals such as oxidized organic material. This subsequent contacting of the electronic components is especially preferred when the ozonated process fluid is used to remove organic materials from the surfaces of the electronic components. The processing solution may be a reactive chemical process liquid or rinsing liquid or combinations thereof.

For example, in one embodiment of the present invention, after contact with the ozonated process fluid, the electronic components are contacted with a cleaning solution such as an SCI solution and/or an SC2 solution. Following contact with the SC1 and/or SC2 solution, the electronic components may be optionally rinsed with a rinsing liquid such as deionized water. Preferably, the SC1 Solution is at a temperature of from about 15° C. to about 95° C., and more preferably from about 25° C. to about 45° C. Preferably, the SC2 Solution is at a temperature of from about 15° C. to about 95° C., and more preferably from about 25° C. to about 45° C. Preferably, the rinsing liquid is at a temperature of from about 15° C. to about 90° C., and more preferably from about 25° C. to about 30° C.

In another embodiment of the present invention, the electronic components may be contacted with an etching solution subsequent to contact with the ozonated process fluid. Where the etching solution contains hydrofluoric acid, preferably the temperature of the hydrofluoric acid is from about 15° C. to about 95° C., and more preferably from about 24° C. to about 40° C. Following etching, the electronic components may be contacted with a rinsing liquid such as deionized water. Preferably the temperature of the rinsing liquid is from about 15° C. to 90° C., and more preferably from about 25° C. to about 30° C.

In another embodiment of the present invention, the electronic components, after contact with the ozonated process fluid, may be contacted with an SC1 solution having a concentration of about 80:3:1 parts by volume H₂O:H₂O₂:NH₄OH; an SC2 solution having a concentration of 80:1:1 parts by volume H₂O:H₂O₂:HCl; and a hydrofluoric acid solution having a concentration of about 4:1 to about 1000:1 parts by volume H₂O:HF. This method is particularly useful for cleaning and etching. However, the SC1 solution, the SC2 solution, and the etching solution may also be used in any sequence.

In a preferred embodiment of the present invention the electronic components, after contact with the ozonated process fluid, are contacted with an SC1 solution, and then contacted with an SC2 solution. The electronic components are then preferably rinsed with deionized water and dried using an isopropanol vapor.

Following wet processing with the ozonated process fluid, reactive chemical process fluids or rinsing fluids, the electronic components are preferably dried. By “dry” or “drying” it is meant that the electronic components are preferably made substantially free of liquid droplets. By removing liquid droplets during drying, impurities present in the liquid droplets do not remain on the surfaces of the semiconductor substrates when the liquid droplets evaporate. Such impurities undesirably leave marks (e.g., watermarks) or other residues on the surfaces of the semiconductor substrates. However, it is also contemplated that drying may simply involve removing a treating, or rinsing fluid, for example with the aid of a drying fluid stream, or by other means known to those skilled in the art. Any method or system of drying may be used. Suitable methods of drying include for example evaporation, centrifugal force in a spin-rinser-dryer, steam or chemical drying, or combinations thereof. In a preferred embodiment, the wet processing and drying is performed in a single processing chamber without removing the electronic components from the processing chamber.

A preferred method of drying uses a drying fluid stream to directly displace the last processing solution that the electronic components are contacted with prior to drying (hereinafter referred to as “direct displace drying”). Suitable methods and systems for direct displace drying are disclosed in for example U.S. Pat. Nos. 4,778,532, 4,795,497, 4,911,761, 4,984,597, 5,571,337, and 5,569,330. Other direct displace dryers that can be used include Marangoni type dryers supplied by manufacturers such as Steag, Dainippon, and YieldUp. Preferably, the drying fluid stream is formed from a partially or completely vaporized drying solution. The drying fluid stream may be for example superheated, a mixture of vapor and liquid, saturated vapor or a mixture of vapor and a noncondensible gas.

The drying solution chosen to form the drying fluid stream is preferably miscible with the last process fluid in the processing chamber and non-reactive with the surfaces of the electronic components. The drying solution also preferably has a relatively low boiling point to facilitate drying. Since water is the most convenient and commonly used solvent for chemical treatment or rinsing fluids, a drying solution which forms a minimum-boiling azeotrope with water is especially preferred. For example, the drying solution is preferably selected from organic compounds having a boiling point of less than about 140° C. at atmospheric pressure. Examples of drying solutions which may be employed are steam, alcohols such as methanol, ethanol, 1-propanol, isopropanol, n-butanol, secbutanol, tertbutanol, or tert-amyl alcohol, acetone, acetonitrile, hexafluoroacetone, nitromethane, acetic acid, propionic acid, ethylene glycol mono-methyl ether, difluoroethane, ethyl acetate, isopropyl acetate, 1,1,2-tricihloro-1,2,2-trifluoroethane, 1,2-dichloroethane, trichloroethane, perfluoro-2-butyltetrahydrofuran, perfluoro-1,4-dimethylcyclohexane or combinations thereof. Preferably, the drying solution is a C₁ to C₆ alcohol, such as for example methanol, ethanol, 1-propanol, isopropanol, n-butanol, secbutanol, tertbutanol, tert-amyl alcohol, pentanol, hexanol or combinations thereof.

Following drying, the electronic components may be removed from the drying processing chamber and further processed in any desired manner.

Although the present invention has been described above with respect to particular preferred embodiments, it will be apparent to those skilled in the art that numerous modifications and variations can be made to those designs. For example, the present invention can be used to provide an ozonated sulfuric acid solution. The descriptions provided are for illustrative purposes and are not intended to limit the invention.

What is claimed is:

1. An apparatus for providing an ozonated process fluid comprising:
a. a vessel for containing a stock fluid;
b. an ozone source operatively connected with the vessel for supplying ozone to the vessel;
c. a fluid source operatively connected and in fluid communication with the vessel for supplying a fluid to the vessel;
d. an exhaust operatively connected and in fluid communication with the vessel for venting fluid from the vessel; and
e. a back-pressure regulator operatively connected with the exhaust for regulating pressure within the vessel.

2. The apparatus of claim 1 wherein the vessel comprises an outlet positioned about an open end of the vessel for connecting the vessel to an injection manifold.

3. The apparatus of claim 2 comprising a screen positioned within the vessel and substantially spanning the open end of the vessel.

4. The apparatus of claim 1 comprising an injection manifold operatively connected and in fluid communication with the vessel for receiving an ozonated fluid from the vessel.

5. The apparatus of claim 4 comprising a water source operatively connected and in fluid communication with the injection manifold for supplying water to the injection manifold.

6. The apparatus of claim 5 comprising an injection controller operatively connected with the injection manifold, the vessel, and the water source for controlling the flow of water and ozonated fluid through the injection manifold.

7. The apparatus of claim 6 comprising a temperature controller operatively associated with the injection manifold for adjusting the temperature of the water from the water source.

8. The apparatus of claim 1 wherein the ozone source comprises an ozone generator operatively connected and in fluid communication with an inlet of the vessel.

9. The apparatus of claim 8 wherein the ozone source comprises a sparger to facilitate the dissolution of ozone in the fluid contained in the vessel.

10. The apparatus of claim 1 wherein the fluid source comprises an inert gas source for supplying an inert gas to the vessel.

11. The apparatus of claim 10 wherein the fluid source comprises a pressure regulator for regulating the pressure of the inert gas.

12. The apparatus of claim 1 comprising a packing material contained within the vessel.

13. A method for producing an ozonated process fluid comprising the steps of:
a. bubbling ozone through a stock fluid contained in a pressurizable vessel;
b. regulating a partial pressure of the ozone within the pressurizable vessel to dissolve ozone within the stock fluid and provide an ozonated fluid; and
c. mixing the ozonated fluid with water to form the ozonated process fluid.

14. A method for processing an electronic component with an ozonated process fluid comprising the steps of:
a. bubbling ozone through a stock fluid contained in a pressurizable vessel;
b. regulating a partial pressure of the ozone within the pressurizable vessel to dissolve ozone within the stock fluid and provide an ozonated fluid; and
c. introducing a fluid into the vessel to expel the ozonated fluid from the vessel and into an injection manifold;
d. supplying a flow of water to the injection manifold such that the water mixes with the ozonated fluid to form the ozonated process fluid; and
e. contacting the electronic component with the ozonated process fluid.

15. The method of claim 14 wherein the ozonated process fluid is maintained at a pressure substantially the same as the partial pressure of the ozone within the pressurizable vessel.

16. The method of claim 14 wherein the ozonated process fluid is returned to the pressurizable vessel after contacting the electronic component.
